(19) United States
(12) Patent Application Publication
(10) Pub. No.: US 2011/0095719 A1
(43) Pub. Date: Apr. 28, 2011

(54) SOLAR CHARGER

(76) Inventor: KEVIN STRICKLAND, Lufkin, TX (US)

(21) Appl. No.: 12/604,388

(22) Filed: Oct. 23, 2009

(51) Int. Cl. H01M 10/46; H01L 31/042

(52) U.S. Cl. 320/101; 136/244

(57) ABSTRACT

The present invention relates to a portable solar charging assembly comprising: a photovoltaic array, where the photovoltaic array is less than 8 square inches and capable of generating electrical energy; a border surrounding the array; an outlet, where said outlet provides a connection point for the connection of a cable; and a cable attachment, where said cable attachment connects the array to a battery and transfers electrical energy from the array to the battery. The cable attachment may include a plug at a first end and an attachment mechanism at the second end. The attachment mechanism may include interchangeable connectors that connect to an electronic device and effects the charging of the battery from energy generated by the array. The portable solar charging assembly may also include a back side of the array and at least one suction cup on the back side.

### BACKGROUND OF THE INVENTION

1. Field of Invention The present invention relates to a miniature pocketsize solar charger that is capable of recharging batteries on electronic devices.

2. Description of Related Art

Electronic devices are used in many facets of modern day life. In particular, numerous cell phones are used by individuals throughout the world; miniature music players such as MP3s, iPods and other devices are also used; digital recording devices, laptop computers, digital cameras, digital video cameras and all other types of electronic devices are used extensively. Many times these devices are powered through the use of a rechargeable battery that allows the user to recharge and repeatedly use the battery while using the electronic device. Many electronic devices include a converter or adapter that charges the battery through the use of an AC outlet. The use of certain devices in certain circumstances is not conducive to utilize an AC outlet to recharge batteries. Occasionally devices are used in remote areas and outdoors and therefore are not within reach of an AC outlet.

Remote chargers have been developed that draw power from a vehicle DC adapter that plug into outlets in vehicles. These adapters are able to recharge the device's battery through the use of a vehicle's electrical power system and therefore provide a remote means of charging an electronic device. In other occasions such types of charging are not available if an individual is hiking or is simply out away from either a vehicle or a building and therefore is unable to readily recharge the battery for the electronic device. It would be advantageous to use solar technology and solar power in order to recharge batteries on electronic devices. A solar option of recharging may be more flexible and readily accessible in outdoor environments.

### SUMMARY OF THE INVENTION

The present invention relates to a portable solar charging assembly comprising: a photovoltaic array, where the photovoltaic array is less than 8 square inches and capable of generating electrical energy; a border surrounding the array; an outlet, where said outlet provides a means for the connection of a cable; and a cable attachment, where said cable attachment provides a means to connect the array to a battery and transfers electrical energy from the array to the battery. The cable attachment may include a plug at a first end and an attachment means at the second end. The attachment means may include interchangeable connectors that connect to an electronic device and effects the charging of the battery from energy generated by the array. The portable solar charging assembly may also include a back side of the array and at least one suction cup on the back side. In one particular embodiment, the portable solar charging assembly may include control buttons, where the control buttons include at least a power charging button and a power storage button.

### BRIEF DESCRIPTION OF DRAWINGS

FIG. 1 provides the overview of a portable solar charging system according to the present invention.

FIG. 2 provides a side view of the solar panel assembly of the portable solar charging system according to the present invention.

FIG. 3 depicts a back view of the portable solar panel according to the present invention.

### DETAILED DESCRIPTION

The present invention relates to a portable solar charging device that provides a portable and effective device for recharging batteries of electronic devices. The solar charger of the present invention may come in various sizes but in one particular embodiment may be small enough to attach to a keychain ring accessory. The solar panel may be small enough to fit in an individual's pocket but yet developed enough strength to transfer electrical power to a connected electrical device.

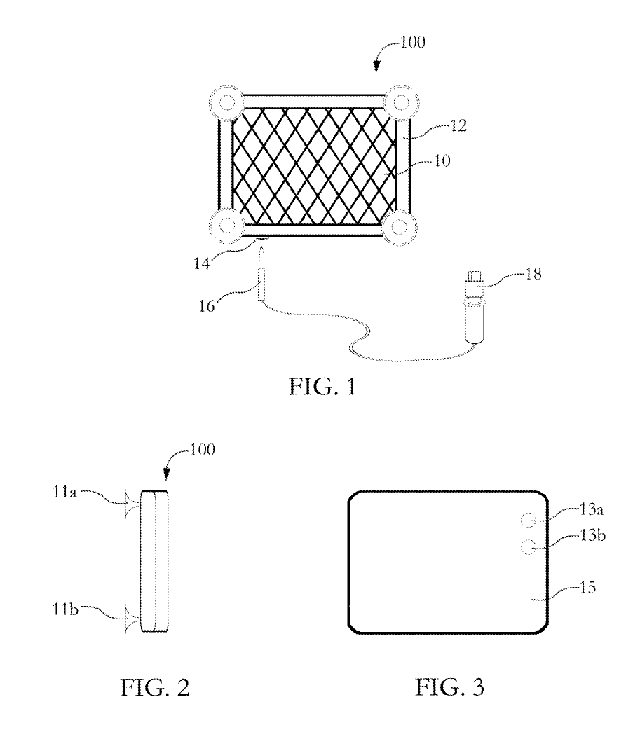

FIG. 1 shows an overview of the solar panel assembly in accordance with the present invention. A solar panel assembly 100 is depicted that includes Solar Panel 10 and a surrounding Border 12. The front side of the Solar Panel 10 is depicted in FIG. 1. The Solar Panel 10 also includes a plug in device that plugs into an Outlet 14 where a Plug 16 inserts into the Outlet 14. At the opposite end of the Plug 16, an Attachment Means 18 is provided that allows the insertion of an electronic device for recharging. Electrical power is collected by the Solar Panel 10 and therefore used to charge any electrical device that is connected to the Attachment Means 18. The Attachment Means 18 is convertible and may be converted to fit various types of electronic devices. FIG. 2 depicts a side view of the solar panel assembly 100 according to the present invention. Suction Cups 11a and 11b may be provided on one side of the charging device and therefore provide a means to attach the panel to a flat surface in order to collect solar energy via the Solar Panel 10. Control buttons are provided on the a back Side 15 of the Solar Panel 10 as depicted in FIG. 3. Control buttons may include a power charging Control 13a and a power storage Control 13b.

The solar charging System 100 is depicted as a small charging panel that may be a pocketsize device and in one particular embodiment, may be up to 2¾ inches in height and 3¾ inches in length. In another particular embodiment, the Solar Panel 10 may be placed upon a key ring and included with a key ring attachment where the Solar Panel 10 may be conveniently placed in an individual's pocket. A charging connection may be provided on this key ring attachment solar panel to provide a connection means for the electronic device.

The portable solar charging system according to the present invention provides solar energy to rechargeable batteries on various electronic devices. The portable solar charging system according to the present invention provides greater convenience to charge portable electronics and may be used in various environments that may have access to sufficient sunlight. The solar panel may be equipped with photovoltaic cells and the conductor cable plugs into the panel as described above. The portable solar charger according to the present invention is especially useful on outdoor expeditions, construction sites and other remote areas where an individual may not be able to obtain an AC or DC outlet to charge the electronic device. The instant invention has been shown and described in what it considers to be the most practical and preferred embodiments. It is recognized, however, that departures may be made there from within the scope of the invention and that obvious modifications will occur to a person skilled in the art.

What is claimed is:

1. A portable solar charging assembly comprising:
a. a photovoltaic array, where the photovoltaic array is less than 8 square inches and capable of generating electrical energy;
b. a border surrounding the array;
c. an outlet, where said outlet provides a means for the connection of a cable; and
d. a cable attachment, where said cable attachment provides a means to connect the array to a battery and transfers electrical energy from the array to the battery.

2. The portable solar charging assembly according to claim 1, where said cable attachment includes a plug at a first end and an attachment means at the second end.

3. The portable solar charging assembly according to claim 2, where said attachment means includes interchangeable connectors, said connectors connect to an electronic device and effects the charging of the battery from energy generated by the array.

4. The portable solar charging assembly according to claim 1, further comprises a back side of the array and at least one suction cup on the back side.

5. The portable solar charging assembly according to claim 4, further comprising control buttons, where the control buttons include at least a power charging button and a power storage button.

6. The portable solar charging assembly according to claim 1, where said array is mounted on a key ring attachment.
